(19) United States
(12) Patent Application Publication
(10) Pub. No.: US 2025/0201515 A1
(43) Pub. Date: Jun. 19, 2025

(54) IMPEDANCE MEASUREMENT METHOD OF SUBSTRATE PROCESSING APPARATUS

(71) Applicant: SEMES CO., LTD., Cheonan-si (KR)

(72) Inventor: Sang Moon YOO, Cheonan-si (KR)

(73) Assignee: SEMES CO., LTD., Cheonan-si (KR)

(21) Appl. No.: 18/945,860

(22) Filed: Nov. 13, 2024

(30) Foreign Application Priority Data
Dec. 13, 2023 (KR) 10-2023-0181061

(51) Int. Cl. H01J 37/32

(52) U.S. Cl. CPC H01J 37/32091; H01J 37/32715; H01J 2237/24564

(57) ABSTRACT

Disclosed are an impedance measurement method capable of measuring impedance of a chamber in various aspects and a control device configured to perform impedance measurement. A substrate processing apparatus includes a chamber and a support unit disposed in the chamber to support a substrate. An RF electrode receiving RF power for generation of plasma and an edge electrode provided outside the substrate are disposed on the support unit. The RF electrode is connected to an RF power supply, thereby supplying the RF power to the RF electrode. The edge electrode is connected to an edge impedance control circuit, thereby adjusting impedance of a peripheral portion of the support unit. The impedance measurement method includes calculating 2-port impedance of the chamber by setting the RF electrode and the edge electrode as 2-port input terminals and 2-port output terminals for various frequencies and storing data on the 2-port impedance of the chamber.

### CROSS-REFERENCE TO THE RELATED APPLICATION

The present application claims priority to and the benefit of Korean Patent Application No. 10-2023-0181061, filed on Dec. 13, 2023, in the Korean Intellectual Property Office, the entire disclosure of which is incorporated herein by reference.

### BACKGROUND

### Technical Field

The present disclosure relates to an impedance measurement method of a substrate processing apparatus and a control device configured to manage the substrate processing apparatus.

### Description of the Related Art

A semiconductor manufacturing process is a process for manufacturing a semiconductor device on a substrate (e.g., a wafer), and includes, for example, photolithography, deposition, etching, ion implantation, and cleaning. In order to perform each manufacturing process, semiconductor manufacturing equipment that performs each process is provided in a clean room of a semiconductor manufacturing facility, and each process is performed on a substrate loaded in the semiconductor manufacturing equipment.

Processes using plasma, for example, etching and deposition, are widely used in the semiconductor manufacturing process. A plasma processing process is performed in such a manner that a substrate is seated at a lower portion in a chamber forming a plasma processing region, process gas for plasma processing is supplied, and power is applied by electrodes located at an upper portion and a lower portion in the chamber.

In order to control plasma more effectively, it is important to previously know the electrical characteristics (e.g., impedance) of the chamber. One example of conventional methods of measuring the impedance of the chamber is to measure the impedance of the chamber using a measurement device such as a probe in a state of forming plasma in the chamber. However, a more precise impedance measurement method is required in order to precisely control plasma and maintain the respective characteristics of the chamber at a constant level.

### SUMMARY

The present disclosure provides an impedance measurement method capable of measuring impedance of a chamber in various aspects and a control device configured to perform impedance measurement.

According to an embodiment of the present disclosure, there is provided an impedance measurement method of a substrate processing apparatus configured to process a substrate using plasma. The substrate processing apparatus includes a chamber forming a processing region for the substrate and a support unit disposed at a lower portion in the chamber to support the substrate from below. The support unit includes an radio frequency (RF) electrode receiving RF power for generating plasma and an edge electrode provided on edge of the support unit. The RF electrode is connected to a RF power supply via an impedance matching circuit, so that the RF power is supplied to the RF electrode. The edge electrode is connected to an edge impedance control circuit including variable impedance elements, so that impedance of a peripheral portion of the support unit is adjusted. The impedance measurement method includes calculating 2-port impedance of the chamber by setting the RF electrode and the edge electrode as 2-port input terminals and 2-port output terminals for various frequencies and storing data on the 2-port impedance of the chamber.

In the embodiment of the present disclosure, calculating the 2-port impedance of the chamber may include calculating a first parameter of the 2-port impedance by setting the edge electrode as an input/output terminal in a state in which the RF power supply and the impedance matching circuit are connected to the RF electrode.

In the embodiment of the present disclosure, calculating the 2-port impedance of the chamber may further include calculating a second parameter of the 2-port impedance by setting the edge electrode as an input terminal and setting the RF electrode as an output terminal.

In the embodiment of the present disclosure, calculating the 2-port impedance of the chamber may further include calculating a third parameter of the 2-port impedance by setting the RF electrode as an input/output terminal in a state in which the edge impedance control circuit is connected to the edge electrode.

In the embodiment of the present disclosure, the 2-port impedance of the chamber may be measured in each of a first state in which a wafer-shaped jig is seated on the support unit and a second state in which the jig is not seated on the support unit.

In the embodiment of the present disclosure, the impedance measurement method may further include outputting distribution of impedance of the chamber for various frequencies.

In the embodiment of the present disclosure, the impedance measurement method may further include outputting an alarm when the distribution of the impedance of the chamber is outside a predetermined reference distribution range.

According to another embodiment of the present disclosure, a control device configured to manage a substrate processing apparatus configured to process a substrate using plasma includes a processor configured to calculate 2-port impedance of the chamber by setting the RF electrode and the edge electrode as 2-port input terminals and 2-port output terminals for various frequencies and a memory configured to store data on the 2-port impedance of the chamber.

According to still another embodiment of the present disclosure, a substrate processing apparatus includes a chamber forming a processing region for a substrate, a support unit disposed at a lower portion in the chamber to support the substrate from below, a gas supply unit configured to supply a process gas to the interior of the chamber, a shower head unit disposed at an upper portion in the chamber to disperse the process gas in the processing region, a baffle unit disposed between an inner side wall of the chamber and the support unit to discharge a gas remaining in the processing region, and an RF power supply configured to supply RF power for generation of the plasma to the support unit. The support unit includes a dielectric plate configured to allow the substrate to be seated thereon, a metal plate disposed below the dielectric plate, an RF plate is an RF electrode disposed below the metal plate, and an edge ring assembly disposed on a peripheral portion of the metal plate so as to surround an periphery of the dielectric plate, the edge ring assembly being provided therein with an edge electrode. The RF plate which is connected to the RF power supply via an impedance matching circuit, so that the RF power is supplied to the RF plate. The edge electrode is connected to an edge impedance control circuit including variable impedance elements, so that impedance of a peripheral portion of the support unit is adjusted. The control device includes a processor configured to calculate 2-port impedance of the chamber by setting the RF electrode and the edge electrode as 2-port input terminals and 2-port output terminals for various frequencies and a memory configured to store data on the 2-port impedance of the chamber.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 shows a control device and a substrate processing apparatus according to the present disclosure;

FIG. 2 is a block diagram showing the configuration of the control device according to the present disclosure;

FIG. 3 shows a substrate processing apparatus according to the present disclosure;

FIG. 4 shows a support unit in the substrate processing apparatus according to the present disclosure;

FIG. 5 is a flowchart showing an impedance measurement method of the substrate processing apparatus according to the present disclosure;

FIGS. 6 to 8 are diagrams for explaining a process of measuring the impedance of a chamber in the substrate processing apparatus according to the present disclosure; and

FIG. 9 shows experimental data indicating an example of distribution of the impedance of the chamber according to frequencies.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is said to be “connected”, “coupled”, or “joined” to another constituent element, the constituent element and the other constituent element may be “directly connected”, “directly coupled”, or “directly joined” to each other, or may be “indirectly connected”, “indirectly coupled”, or “indirectly joined” to each other with one or more intervening elements interposed therebetween. In addition, throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

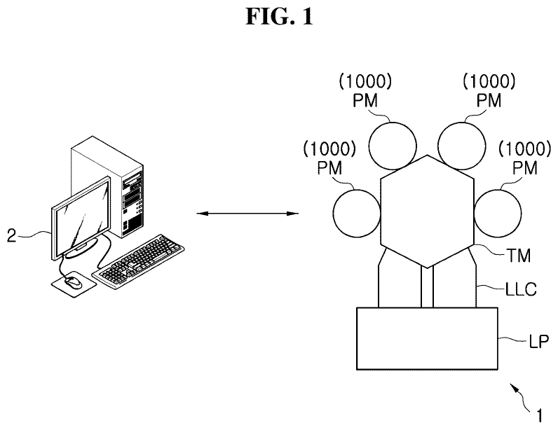

FIG. 1 shows a control device 2 and semiconductor manufacturing equipment 1 according to the present disclosure. Referring to FIG. 1, the semiconductor manufacturing equipment 1 includes a load port LP, a load lock chamber LLC, a transfer module TM, and a processing module PM. The load port LP provides a space in which a container containing a substrate (e.g., wafer) is placed, and takes the substrate out of the container to transfer the substrate to the load lock chamber LLC or loads a substrate placed in the load lock chamber LLC in the container. The load lock chamber LLC temporarily stores the substrate, and the transfer module TM transfers the substrate from the load lock chamber LLC to the processing module PM, and transfers the substrate from the processing module PM to the load lock chamber LLC. The processing module PM performs a processing process on the substrate. For example, the processing module PM may be a device that performs a dry etching process to remove a specific portion of the substrate using plasma. The control device 2 is a device for controlling the components (e.g., the processing module PM and the transfer module TM) of the semiconductor manufacturing equipment 1.

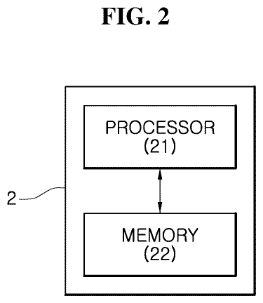

FIG. 2 is a block diagram showing the configuration of the control device 2 according to the present disclosure. The control device 2 may include a processor 21 and a memory 22. The processor 21 may execute commands for controlling operation of the semiconductor manufacturing equipment 1 and may perform data processing and calculation. The processor 21 may be a central processing unit (CPU) or an application processor (AP). The processor 21 may acquire and store data through communication with the memory 22 and may control the memory 22.

The memory 22 is provided to store data. The memory 22 may store programs (e.g., an operating system and an application) for operation of a control module Cont and data for execution of the programs. The memory 22 may be random access memory (RAM), read-only memory (ROM), a hard disk drive (HDD), or a solid state drive (SSD). The memory 22 may be connected to the processor 21 via a data bus to transmit and receive data.

Although not shown in FIG. 2, the control device 2 may include a communication module capable of communicating with an external entity and an input/output interface connected to input devices (e.g., a keyboard, a mouse, and a touch panel) and output devices (e.g., a display and a speaker) for interfacing with a user.

In addition, the processor 21 may monitor the current state of the semiconductor manufacturing equipment 1, and may output an alarm indicating malfunction to a manager when the semiconductor manufacturing equipment 1 malfunctions. The processor 21 may receive data related to the semiconductor manufacturing equipment 1 and store the data in the memory 22 at the initial stage of installation of the semiconductor manufacturing equipment 1.

The processor 21 may execute a desired process such as etching in accordance with various recipes stored in the memory 22. Apparatus control information for process conditions, including a process time, a process pressure, high-frequency power, a voltage, various gas flow rates, temperatures in the chamber (e.g., an electrode temperature, a chamber sidewall temperature, and an electrostatic chuck temperature), and the temperature of a cooler, is written in the recipes. The memory 22 stores data on the recipes.

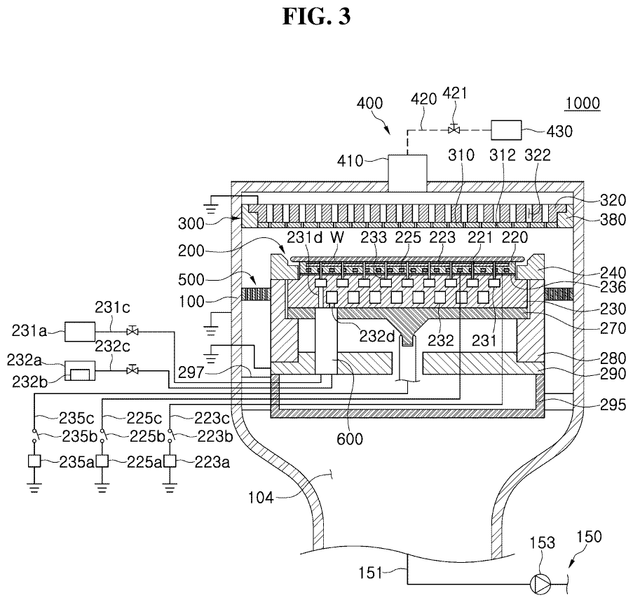

FIG. 3 shows a substrate processing apparatus 1000 according to the present disclosure. The substrate processing apparatus 1000 shown in FIG. 3 corresponds to the processing module PM in the semiconductor manufacturing equipment 1 shown in FIG. 1. That is, the control device 2 controls the substrate processing apparatus 1000 shown in FIG. 3, and processes data related to the substrate processing apparatus 1000. In the present disclosure, the processor 21 of the control device 2 may calculate the impedance of a chamber 100 in the substrate processing apparatus 1000 and may store the calculated impedance in the memory 22.

Referring to FIG. 3, the substrate processing apparatus 1000 includes a chamber 100, a support unit 200, a shower head unit 300, a gas supply unit 400, a plasma source, a liner unit (not shown), and a baffle unit 500.

The chamber 100 forms a processing region in which a substrate processing process is performed. The chamber 100 is provided in a sealed shape. The chamber 100 may be made of a conductive material. For example, the chamber 100 may be made of a material including a metal. The chamber 100 may be made of aluminum. The chamber 100 may be grounded. An exhaust hole 104 is formed in the bottom surface of the chamber 100. The exhaust hole 104 is connected to an exhaust line 151. The exhaust line 151 is connected to a pump 153. Reaction by-products generated during the process and gas remaining in the space in the chamber 100 may be discharged to the outside through the exhaust line 151. The internal pressure of the chamber 100 is reduced to a predetermined level by the exhaust process. Alternatively, a separate pressure-reducing member may be provided to reduce the internal pressure of the processing region 102 to a predetermined level.

A heater (not shown) may be provided on the wall of the chamber 100. The heater heats the wall of the chamber 100. The heater is electrically connected to a heating power supply (not shown). The heater resists a current applied thereto from the heating power supply to generate heat. The heat generated by the heater is transferred to the internal space. The temperature in the processing region is maintained at a predetermined level by the heat generated by the heater. The heater may be provided as a coil-shaped heating wire. A plurality of heaters may be provided on the wall of the chamber 100.

The support unit 200 is located in the chamber 100. The support unit 200 supports the substrate W in the processing region. The support unit 200 may be provided as an electrostatic chuck (ESC) that attracts and holds the substrate W using electrostatic force. Alternatively, the support unit 200 may support the substrate W in various other ways, such as mechanical clamping.

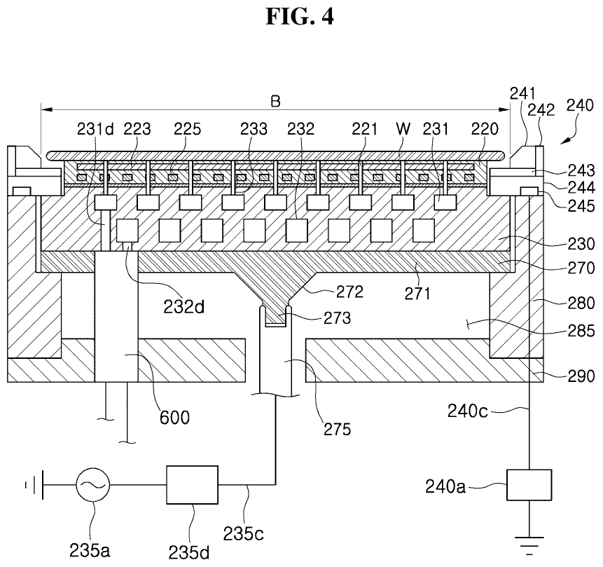

FIG. 4 shows the support unit 200 in the substrate processing apparatus 1000 according to the present disclosure. The support unit 200 includes a dielectric plate 220, a metal plate 230, an edge ring assembly 240, a radio frequency (RF) plate 270, an insulating cover 280, a base plate 290, a lower cover 295, and a fluid connection block 600. The support unit 200 may be located in the chamber 100 so as to be spaced upward from the bottom surface of the chamber 100.

The dielectric plate 220 is located at the top of the support unit 200. The dielectric plate 220 is provided as a disc-shaped dielectric substance. The substrate W is placed on the upper surface of the dielectric plate 220. The upper surface of the dielectric plate 220 has a smaller radius than the substrate W. Therefore, the peripheral area of the substrate W is located outside the dielectric plate 220. A first supply channel 221 is formed in the dielectric plate 220. The first supply channel 221 is formed from the upper surface of the dielectric plate 220 to the lower surface of the dielectric plate 220. A plurality of first supply channels 221 may be formed so as to be spaced apart from each other, and may serve as passages through which a heat transfer medium is supplied to the lower surface of the substrate W.

An electrostatic electrode 223 and a heater 225 are embedded in the dielectric plate 220. The electrostatic electrode 223 is located above the heater 225. The electrostatic electrode 223 is electrically connected to a direct current (DC) power supply 223a. A switch 223b is mounted between the electrostatic electrode 223 and the DC power supply 223a. The electrostatic electrode 223 may be electrically connected to the DC power supply 223a by turning the switch 223b on/off. When the switch 223b is turned on, direct current is applied to the electrostatic electrode 223. Electrostatic force is exerted between the electrostatic electrode 223 and the substrate W by the current applied to the electrostatic electrode 223, and the substrate W is attracted to and held by the dielectric plate 220 due to the electrostatic force.

The heater 225 is electrically connected to a heater power supply 225a. The heater 225 resists a current applied thereto from the heater power supply 225a to generate heat. The generated heat is transferred to the substrate W through the dielectric plate 220. The temperature of the substrate W is maintained at a predetermined level by the heat generated by the heater 225. The heater 225 includes a spiral coil.

The metal plate 230 is located below the dielectric plate 220. The lower surface of the dielectric plate 220 and the upper surface of the metal plate 230 may be adhered to each other by means of an adhesive 236. The metal plate 230 may be made of aluminum. The upper surface of the metal plate 230 may be stepped such that the central area thereof is located at a position higher than the peripheral area thereof. The central area of the upper surface of the metal plate 230 has an area corresponding to the lower surface of the dielectric plate 220, and is adhered to the lower surface of the dielectric plate 220. A first circulation flow path 231, a second circulation flow path (coolant flow path) 232, and a second supply flow path 233 are formed in the metal plate 230.

The metal plate 230 may be connected to a high-frequency power supply via a high-frequency transmission line. Power may be applied to the metal plate 230 from the high-frequency power supply, so that plasma generated in the processing region may be smoothly supplied to the substrate. That is, the metal plate 230 may function as an electrode. In addition, although the substrate processing apparatus 1000 is illustrated in FIG. 3 as being implemented as a capacitively coupled plasma (CCP) type, the disclosure is not limited thereto. The substrate processing apparatus 1000 according to the embodiment of the present disclosure may be implemented as an inductively coupled plasma (ICP) type. When the substrate processing apparatus 1000 is implemented as an ICP type, the high-frequency transmission line may be connected to a lower electrode for generating plasma to apply power from the high-frequency power supply to the lower electrode.

The first circulation flow path 231 is provided as a passage through which a heat transfer medium circulates. The first circulation flow path 231 may be formed in a spiral shape in the metal plate 230. Alternatively, a plurality of ring-shaped first circulation flow paths 231 may be disposed concentrically while having different radii. The plurality of first circulation flow paths 231 may communicate with each other. The first circulation flow paths 231 are formed at the same height.

The second circulation flow path 232 is provided as a passage through which a cooling fluid circulates. The second circulation flow path 232 may be formed in a spiral shape in the metal plate 230. Alternatively, a plurality of ring-shaped second circulation flow paths 232 may be disposed concentrically while having different radii. The plurality of second circulation flow paths 232 may communicate with each other. The second circulation flow paths 232 may have a greater cross-sectional area than the first circulation flow paths 231. The second circulation flow paths 232 are formed at the same height. The second circulation flow paths 232 may be located below the first circulation flow paths 231.

A plurality of second supply flow paths 233 extends upward from the first circulation flow paths 231 to the upper surface of the metal plate 230. The number of second supply flow paths 233 is identical to the number of first supply flow paths 221. The second supply flow paths 233 connect the first circulation flow paths 231 to the first supply flow paths 221.

The first circulation flow path 231 is connected to a heat transfer medium storage unit 231a via a first circulation flow path supply line 231d, the fluid connection block 600, and a heat transfer medium supply line 231c. A heat transfer medium is stored in the heat transfer medium storage unit 231a. The heat transfer medium includes inert gas. According to the embodiment, the heat transfer medium includes helium (He) gas. The helium gas is supplied to the fluid connection block 600 through the heat transfer medium supply line 231c, is supplied to the first circulation flow path 231 from the fluid connection block 600 through the first circulation flow path supply line 231d, and then is supplied to the lower surface of the substrate W from the first circulation flow path 231 through the second supply flow path 233. The helium gas serves as a medium through which heat transferred from the plasma to the substrate W is transferred to the electrostatic chuck.

The second circulation flow path 232 is connected to a cooling fluid storage unit 232a via a second circulation flow path supply line 232d, the fluid connection block 600, and a cooling fluid supply line 232c. A cooling fluid is stored in the cooling fluid storage unit 232a. A cooler 232b may be provided in the cooling fluid storage unit 232a. The cooler 232b cools the cooling fluid to a predetermined temperature. Alternatively, the cooler 232b may be mounted on the cooling fluid supply line 232c. The cooling fluid supplied to the fluid connection block 600 through the cooling fluid supply line 232c is supplied to the second circulation flow path 232 through the second circulation flow path supply line 232d, and circulates along the second circulation flow path 232 to cool the metal plate 230. As the metal plate 230 is cooled, the dielectric plate 220 and the substrate W are also cooled, whereby the temperature of the substrate W is maintained at a predetermined level.

The edge ring assembly 240 is disposed in the peripheral area of the electrostatic chuck. The edge ring assembly 240 has a ring shape and is disposed along the periphery of the dielectric plate 220. In addition, the edge ring assembly 240 may be disposed on the upper surface of the insulating cover 280. Referring to FIG. 3, the edge ring assembly 240 includes a focus ring 241 and an upper insulating ring 242. The focus ring 241 is formed on an inner side of the upper insulating ring 242 so as to surround the dielectric plate 220. The focus ring 241 may be made of silicon, and may focus ions generated during the plasma process on the peripheral portion of the substrate W. The upper insulating ring 242 is formed on an outer side of the focus ring 241 so as to surround the focus ring 241. The upper insulating ring 242 may be made of quartz.

A metal ring 243 made of aluminum is formed on a lower side of the focus ring 241. A lower insulating ring 244 made of an insulating material is formed on lower sides of the metal ring 243 and the upper insulating ring 242. An edge electrode ring 245 is inserted into the lower insulating ring 244. The edge electrode ring 245 is made of a conductive material. The edge electrode ring 245 is connected to an edge impedance control circuit 240a via an edge electrode line 240c. The edge electrode ring 245 is provided to control the impedance of a peripheral portion of the support unit 200. The edge electrode ring 245 corresponds to an edge electrode.

The edge impedance control circuit 240a includes one or more impedance elements (capacitors and inductors). At least one of the impedance elements of the edge impedance control circuit 240a may be a variable impedance element (e.g., a variable capacitor). The impedance of the edge impedance control circuit 240a may be adjusted by controlling the variable impedance element of the edge impedance control circuit 240a. For example, the impedance control circuit 240a may include a mechanical vacuum variable capacitor (VVC), and the impedance of the impedance control circuit 240a may be controlled through mechanical operation of the mechanical vacuum variable capacitor.

An air gap 285 is formed below the metal plate 230. The air gap 285 is formed between the RF plate 270 and a base plate 290 to be described later. The air gap 285 may be surrounded by the insulating cover 280. The air gap 285 electrically insulates the RF plate 270 and the base plate 290 from each other.

The RF plate 270, which is an RF electrode, is provided below the metal plate 230. The upper surface of the RF plate 270 is in contact with the lower surface of the metal plate 230. The planar shape of the RF plate 270 may be a disc shape. The RF plate 270 is made of a conductive material. For example, the RF plate 270 may be made of aluminum.

The RF plate 270 includes an electrode plate portion 721, a deformed portion 272, and a rod coupling portion 273. The electrode plate portion 271 is formed to have a planar shape corresponding to the planar shape of the metal plate 230. The deformed portion 272 extends downward from the center of the electrode plate portion 271. The deformed portion 272 may be formed such that the diameter thereof gradually decreases in a downward direction. The rod coupling portion 273 extends downward from the lower side of the deformed portion 272.

A power supply rod 275 may apply power to the RF plate 270. The power supply rod 275 may be electrically connected to the RF plate 270. The power supply rod 275 may be connected to an RF power supply 235a. The RF power supply 235a generates RF power. The RF power supply 235a may be provided as a high bias power RF power supply. The RF power supply 235a may include a plurality of RF power supplies. The plurality of RF power supplies may be configured as a combination of one or more of high frequency (27.12 MHz or higher), medium frequency (1 MHz to 27.12 MHz), and low frequency (100 kHz to 1 MHz). The power supply rod 275 receives high-frequency power from the RF power supply 235a. The power supply rod 275 may be made of a conductive material. For example, the power supply rod 275 may be made of a material including a metal. The power supply rod 275 may be a metal rod. In addition, the power supply rod 275 may be connected to an impedance matching circuit 235d. The RF power supply 235a and the power supply rod 275 may be connected to each other via the impedance matching circuit 235d. The impedance matching circuit 235d includes impedance elements for impedance matching so that maximum power is transferred from the RF power supply 235a to the plasma load. The impedance matching circuit 235d includes one or more impedance elements (capacitors and inductors). At least one of the impedance elements of the impedance matching circuit 235d may be a variable impedance element (e.g., a variable capacitor).

The insulating cover 280 supports the RF plate 270. The insulating cover 280 may be provided so as to be in contact with the side surface of the RF plate 270. The insulating cover 280 may be provided so as to be in contact with a peripheral area of the lower surface of the RF plate 270. For example, the insulating cover 280 may have a tubular shape having open upper and lower portions. In addition, the insulating cover 280 may have a stepped inner side so that the RF plate 270 is supported by the insulating cover 280. The insulating cover 280 may be made of an insulative material.

The base plate 290 is configured to be electrically grounded. A through-hole through which the power supply rod 275 passes is formed in the center of the base plate 290.

The fluid connection block 600 is coupled to the RF plate 270 and the base plate 290 on the lower surface of the metal plate 230. The fluid connection block 600 supplies the heat transfer medium supplied from the heat transfer medium supply line 231c and the cooling fluid supplied from the cooling fluid supply line 232c to the first circulation flow path 231 and the second circulation flow path 232, respectively.

The lower cover 295 is located at the bottom of the support unit 200. The lower cover 295 is spaced upward from the bottom of the chamber 100. The lower cover 295 has defined therein a space having an open upper surface. The upper surface of the lower cover 295 is covered by the base plate 290. Therefore, the outer radius of the cross-section of the lower cover 295 may be formed to be identical to the outer radius of the base plate 290. A lift pin module (not shown), which moves a substrate W transferred from an external transfer member to a substrate support surface, i.e., the upper surface of the support unit 200, may be provided in the space in the lower cover 295.

The lower cover 295 includes a connecting member 297. The connecting member 297 connects the outer side surface of the lower cover 295 to the inner side wall of the chamber 100. A plurality of connecting members 297 may be provided at regular intervals on the outer side surface of the lower cover 295. The connecting members 297 support the support unit 200 in the chamber 100. In addition, the connecting members 297 are connected to the inner side wall of the chamber 100 so that the lower cover 295 is electrically grounded. A DC power line 223c connected to the DC power supply 223a, a heater power line 225c connected to the heater power supply 225a, an RF power line 235c connected to the RF power supply 235a, the heat transfer medium supply line 231c connected to the heat transfer medium storage unit 231a, and the cooling fluid supply line 232c connected to the cooling fluid storage unit 232a extend to the interior of the lower cover 295 through spaces in the connecting members 297.

The lower cover 295 is disposed below the insulating cover 280. The lower cover 295 is disposed below the insulating cover 280 to support the insulating cover 280. In addition, the lower cover 295 may be made of a conductive material. For example, the lower cover 295 may be made of a material including a metal. In addition, the lower cover 295 may be electrically connected to the chamber 100. The lower cover 295 may be electrically grounded.

Referring to FIG. 1, the shower head unit 300 may disperse gas supplied from above. In addition, the shower head unit 300 may allow gas supplied from the gas supply unit 400 to be uniformly supplied to the processing region. The shower head unit 300 includes a shower head 310 and a gas spray plate 320.

The shower head 310 is disposed below the gas spray plate 320. The shower head 310 is spaced downward from the top surface of the chamber 100 by a predetermined distance. The shower head 310 is located above the support unit 200. A certain space is defined between the shower head 310 and the top surface of the chamber 100. The shower head 310 may be formed in a plate shape having a constant thickness. The lower surface of the shower head 310 may be anodized in order to prevent the occurrence of arc due to plasma. The shower head 310 may be formed to have the same cross-sectional shape and cross-sectional area as the support unit 200. A plurality of gas supply holes 312 is formed in the shower head 310. The gas supply holes 312 may be formed so as to vertically penetrate the upper and lower surfaces of the shower head 310.

The shower head 310 may be made of a material that reacts with plasma generated from gas supplied from the gas supply unit 400 to generate a compound. For example, the shower head 310 may be made of a material that reacts with an ion having the highest electronegativity among ions included in the plasma to generate a compound. For example, the shower head 310 may be made of a material including silicon (Si).

The gas spray plate 320 is disposed on the shower head 310. The gas spray plate 320 is spaced a predetermined distance from the top surface of the chamber 100. The gas spray plate 320 may diffuse gas supplied from above. A plurality of gas introduction holes 322 may be formed in the gas spray plate 320. The gas introduction holes 322 may be formed at positions corresponding to the above-described gas supply holes 312. The gas introduction holes 322 may communicate with the gas supply holes 312. The gas supplied from above the shower head unit 300 may sequentially pass through the gas introduction holes 322 and the gas supply holes 312, and may then be supplied to a lower portion of the shower head 310. The gas spray plate 320 may include a metal. The gas spray plate 320 may be grounded. The gas spray plate 320 may be grounded to function as an upper electrode.

An insulating ring 380 is disposed so as to surround the peripheries of the shower head 310 and the gas spray plate 320. The insulating ring 380 may be formed in a circular ring shape on the whole. The insulating ring 380 may be made of a nonmetallic material.

The gas supply unit 400 supplies a process gas to the interior of the chamber 100. The gas supply unit 400 includes a gas supply nozzle 410, a gas supply line 420, and a gas storage unit 430. The gas supply nozzle 410 may be mounted to the central portion of the top of the chamber 100. An injection port is formed in the bottom surface of the gas supply nozzle 410. The process gas supplied through the gas supply nozzle 410 passes through the shower head unit 300, and is supplied to the processing region in the chamber 100. The gas supply line 420 connects the gas storage unit 430 to the gas supply nozzle 410. The gas supply line 420 supplies the process gas stored in the gas storage unit 430 to the gas supply nozzle 410. A valve 421 is mounted on the gas supply line 420. The valve 421 opens and closes the gas supply line 420 to control the flow rate of the process gas supplied through the gas supply line 420.

The gas supplied from the gas supply unit 400 may be excited to a plasma state by a plasma source. In addition, the gas supplied from the gas supply unit 400 may be a gas containing fluorine. For example, the gas supplied from the gas supply unit 400 may be carbon tetrafluoride.

The plasma source excites the process gas to a plasma state in the chamber 100. In the embodiment of the present disclosure, capacitively coupled plasma (CCP) is used as a plasma source. The capacitively coupled plasma may include an upper electrode and a lower electrode in the chamber 100. The upper electrode and the lower electrode may be disposed parallel to each other at an upper portion and a lower portion in the chamber 100. One of the two electrodes may apply high-frequency power, and the other thereof may be grounded. An electromagnetic field may be formed in the space between the two electrodes, and the process gas supplied to this space may be excited to a plasma state. A substrate processing process is performed using this plasma. In one example, the upper electrode may be provided as the shower head unit 300, and the lower electrode may be provided as a combination of the metal plate 230 and the RF plate 270. High-frequency power may be applied to the lower electrode, and the upper electrode may be grounded. Alternatively, high-frequency power may be applied to both the upper electrode and the lower electrode. Accordingly, an electromagnetic field is generated between the upper electrode and the lower electrode. The generated electromagnetic field excites the process gas supplied to the interior of the chamber 100 to a plasma state.

The liner unit (not shown) prevents the inner wall of the chamber 100 and the support unit 200 from being damaged during the process. The liner unit (not shown) prevents impurities generated during the process from being deposited on the inner wall of the chamber 100 and the support unit 200. The liner unit (not shown) includes an inner liner (not shown) and an outer liner (not shown).

The outer liner (not shown) is provided on the inner wall of the chamber 100. The outer liner (not shown) has defined therein a space having open upper and lower surfaces. The outer liner (not shown) may be formed in a cylindrical shape. The outer liner (not shown) may have a radius corresponding to the inner side surface of the chamber 100. The outer liner (not shown) is provided along the inner side surface of the chamber 100. The outer liner (not shown) may be made of aluminum. The outer liner (not shown) protects the inner side surface of the chamber 100. During the process in which the process gas is excited, arc discharge may occur in the chamber 100. Arc discharge damages the chamber 100. The outer liner (not shown) protects the inner side surface of the chamber 100 by preventing the inner side surface of the chamber 100 from being damaged by arc discharge.

The inner liner (not shown) is provided so as to surround the support unit 200. The inner liner (not shown) is formed in a ring shape. The inner liner (not shown) is provided so as to surround the insulating cover 280. The inner liner (not shown) may be made of aluminum. The inner liner (not shown) protects the outer side surface of the support unit 200.

The baffle unit 500 is located between the inner side wall of the chamber 100 and the support unit 200. The baffle unit 500 is formed in an annular ring shape. A plurality of through-holes is formed in the baffle unit 500. The gas supplied to the interior of the chamber 100 passes through the through-holes in the baffle unit 500, and is discharged to the exhaust hole 104. The flow of the gas may be controlled in accordance with the shape of the baffle unit 500 and the shape of the through-holes.

Hereinafter, a method of measuring the impedance of the chamber 100 in the substrate processing apparatus 1000 according to an embodiment of the present disclosure will be described. In the process of setting the parameters of the RF power supply 235a, the impedance matching circuit 235d, and the edge impedance control circuit 240a in order to control the plasma characteristics, impedance information of the chamber 100 is required. The conventional impedance measurement method is to measure impedance using a probe after forming plasma in the chamber 100. According to the impedance measurement method of the present disclosure, the impedance of the chamber 100 may be measured in a passive manner in the state in which plasma is not formed. Accordingly, it is possible to measure impedance for various parts of the chamber 100 and various frequencies.

The substrate processing apparatus 1000 to which the present disclosure is applied includes a chamber 100, which defines a processing region for a substrate W, and a support unit 200, which is disposed at a lower portion in the chamber 100 to support the substrate W from below and in which an RF electrode (RF plate 270) to which RF power for generating plasma is applied and an edge electrode (edge electrode ring 244) provided outside the substrate W are disposed. In the substrate processing apparatus 1000 of the present disclosure, the RF electrode (RF plate 270) is connected to the RF power supply 235a via the impedance matching circuit 235d, so that RF power is supplied to the RF electrode. In addition, the edge electrode (edge electrode ring 244) is connected to the edge impedance control circuit 240a composed of variable impedance elements, so that the impedance of a peripheral portion of the support unit 200 is adjusted.

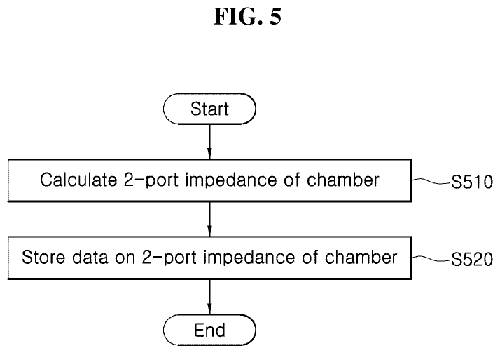

FIG. 5 is a flowchart showing an impedance measurement method of the substrate processing apparatus 1000 according to the present disclosure. The impedance measurement method of the substrate processing apparatus 1000 according to the present disclosure includes a step of calculating 2-port impedance of the chamber 100 by setting the RF electrode and the edge electrode as 2-port input terminals and 2-port output terminals for various frequencies (S510) and a step of storing data on the 2-port impedance of the chamber 100 (S520).

In step S510, the processor 21 calculates the 2-port impedance of the chamber 100 based on the data (current and voltage data) measured by setting the RF electrode and the edge electrode as 2-port input terminals and 2-port output terminals. The 2-port impedance of the chamber 100 defines a relationship between the two input terminal and output terminal from the following 2-port input/output relationship. The 2-port impedance is expressed as a 2×2 matrix, and includes a first parameter S11, second parameters S12 and S21 (S12=S21), and a third parameter S22.

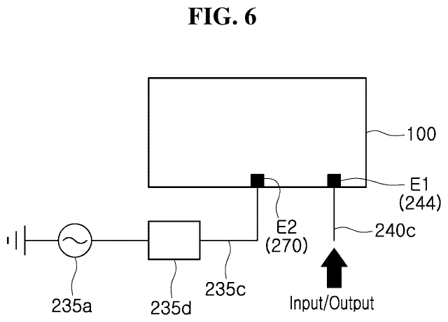

FIGS. 6 to 8 are diagrams for explaining a process of measuring the impedance of the chamber in the substrate processing apparatus according to the present disclosure. The step of calculating the 2-port impedance of the chamber (S510) includes a step of calculating the first parameter S11 of the 2-port impedance by setting the edge electrode E1 as an input/output terminal in a state in which the RF power supply 235a and the impedance matching circuit 235d are connected to the RF electrode. The first parameter S11 means impedance when the edge electrode E1 of the chamber 100 is set as an input/output terminal. The processor 21 may calculate the first parameter S11 of the 2-port impedance by setting the edge electrode E1 as an input/output terminal in a state in which the RF power supply 235a and the impedance matching circuit 235d are connected to the RF electrode E2. As shown in FIG. 6, the first parameter S11 may be calculated by applying a test signal (e.g., V1) to the edge electrode E1 and measuring a response signal (e.g., I1) from the edge electrode E1 in a state in which the RF electrode E2 is connected to the impedance matching circuit 235d and the RF power supply 235a via the RF power line 235c and the edge electrode E1 is open. For example, the first parameter S11 may be calculated as a ratio of voltage V1 applied to the edge electrode E1 to current I1 measured from the edge electrode E1.

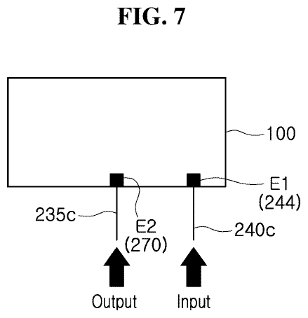

The step of calculating the 2-port impedance of the chamber (S510) includes a step of calculating the second parameters S12 and S21 of the 2-port impedance by setting the edge electrode E1 as an input terminal and setting the RF electrode E2 as an output terminal. Each of the second parameters S12 and S21 is impedance when one of the edge electrode E1 and the RF electrode E2 of the chamber 100 is set as an input terminal and the other thereof is set as an output terminal. As the second parameters, S12 and S21 have the same value. The processor 21 calculates the second parameters S12 and S21 of the 2-port impedance by setting the edge electrode E1 as an input terminal and setting the RF electrode E2 as an output terminal. For example, as shown in FIG. 7, the second parameters S12 and S21 may be calculated by applying a test signal to the edge electrode E1 and measuring a response signal from the RF electrode E2 in a state in which both the RF electrode E2 and the edge electrode E1 are open. For example, each of the second parameters S12 and S21 may be calculated as a ratio of voltage V1 applied to the edge electrode E1 to current I2 measured from the RF electrode E2 or a ratio of voltage V2 applied to the RF electrode E2 to current I1 measured from the edge electrode E1.

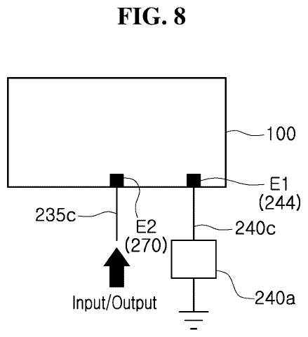

The step of calculating the 2-port impedance of the chamber (S510) includes a step of calculating the third parameter S22 of the 2-port impedance by setting the RF electrode E2 as an input/output terminal in a state in which the edge impedance control circuit 240a is connected to the edge electrode E1. The processor 21 calculates the third parameter S22 of the 2-port impedance by setting the RF electrode E2 as an input/output terminal in a state in which the edge impedance control circuit 240a is connected to the edge electrode E1. Referring to FIG. 8, the third parameter S22 may be calculated by applying a test signal to the RF electrode E2 and measuring a response signal from the RF electrode E2 in a state in which the edge impedance control circuit 240a is connected to the edge electrode E1 and the RF electrode E2 is open. For example, the third parameter S22 may be calculated as a ratio of voltage V2 applied to the RF electrode E2 to current I2 measured from the RF electrode E2.

According to the embodiment of the present disclosure, the 2-port impedance of the chamber 100 may be measured in each of a first state in which a wafer-shaped jig is seated on the support unit 200 and a second state in which the jig is not seated on the support unit 200. The impedance of the chamber 100 may be different depending on whether the substrate W is placed in the chamber 100. Therefore, the 2-port impedance of the chamber 100 in the first state in which the wafer-shaped jig is seated on the support unit 200 and the 2-port impedance of the chamber 100 in the second state in which the jig is not seated on the support unit 200 may be measured, respectively.

The step of calculating the 2-port impedance of the chamber 100 (S510) may be performed while varying the frequency of an input signal within a predetermined range. That is, the 2-port impedance of the chamber 100 may be measured for various frequencies. Accordingly, the 2-port impedance of the chamber 100 may be acquired as data that varies for various frequencies.

When the 2-port impedance of the chamber 100 is measured through the above process, the processor 21 may store data on the 2-port impedance of the chamber 100 in the memory 22 at various frequencies.

The impedance measurement method of the substrate processing apparatus 1000 according to the present disclosure may further include a step of outputting distribution of the impedance of the chamber 100 for various frequencies. The processor 21 may output distribution of the impedance of the chamber 100 for various frequencies. The processor 21 may output distribution of the impedance of the chamber 100 through a display. Here, the distribution of the impedance of the chamber 100 may be one of the first parameter S11, the second parameters S12 and S21, and the third parameter S22 in the matrix representing the 2-port impedance of the chamber 100.

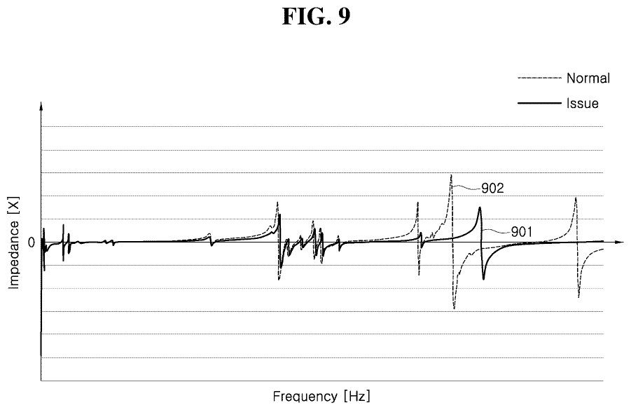

FIG. 9 shows experimental data indicating an example of distribution of the impedance of the chamber 100 according to frequencies. As shown in FIG. 9, distribution of the impedance values of the chamber 100 for various frequencies may be output. An operator may monitor the distribution of the impedance of the chamber 100 to determine whether the chamber 100 is in a normal state.

In addition, the impedance measurement method of the substrate processing apparatus 1000 according to the present disclosure may further include a step of outputting an alarm when the distribution of the impedance of the chamber 100 is outside a predetermined reference distribution range. The processor 21 may output an alarm when the distribution of the impedance of the chamber 100 is outside a predetermined reference distribution range. The processor 21 may distinguish between normal impedance distribution 901 and abnormal impedance distribution 902 based on previously input data on the impedance distribution of the chamber 100 or learning data on the impedance distribution of the chamber 100 in a plurality of substrate processing apparatuses 1000.

Upon receiving input data for measurement of the 2-port impedance of the chamber 100, i.e., a test signal input to the input terminal and a response signal output from the output terminal for various frequencies, the processor 21 may calculate 2-port parameters of the chamber 100 to acquire data on the impedance distribution of the chamber 100 for each frequency. The processor 21 may compare the impedance distribution of the chamber 100 for each frequency with the previously stored or learned normal impedance distribution, and may determine, based on a result of the comparison, whether the acquired impedance distribution of the chamber 100 is normal or abnormal.

Through the above-described process, the impedance of the chamber 100 may be measured in a state in which plasma is not formed in the chamber 100. In particular, the 2-port impedance is measured through the RF electrode E2 and the edge electrode E1. Thus, information about the impedance of each part of the chamber 100 may be acquired. In addition, according to the present disclosure, since 2-port impedance is measured for various frequencies, data on the impedance distribution of the chamber 100 for each operating frequency may be acquired. In addition, impedance data, which is different depending on the presence or absence of a wafer-shaped jig on the support unit in the chamber 100, may be acquired, and accordingly, a variety of impedance data may be acquired according to the internal environment of the chamber 100.

As is apparent from the above description, according to the present disclosure, the impedance of a chamber may be measured in a passive manner in a state in which plasma is not formed in a substrate processing apparatus. Accordingly, it is possible to measure impedance for various parts of the chamber and various frequencies.

Although the preferred embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the appended claims, and all technical ideas within the scope of equivalents to the claims should be construed as falling within the scope of the disclosure.

What is claimed is:

1. An impedance measurement method of a substrate processing apparatus configured to process a substrate using plasma, wherein the substrate processing apparatus comprises:
a chamber forming a processing region for the substrate; and
a support unit disposed at a lower portion in the chamber to support the substrate from below, the support unit including a radio frequency (RF) electrode receiving RF power for generating the plasma and an edge electrode provided on edge of the support unit,
wherein the RF electrode is connected to a RF power supply via an impedance matching circuit, so that the RF power is supplied to the RF electrode,
wherein the edge electrode is connected to an edge impedance control circuit comprising variable impedance elements, so that impedance of a peripheral portion of the support unit is adjusted, and
wherein the impedance measurement method comprises:
calculating 2-port impedance of the chamber by setting the RF electrode and the edge electrode as 2-port input terminals and 2-port output terminals for various frequencies; and
storing data on the 2-port impedance of the chamber.

2. The impedance measurement method as claimed in claim 1, wherein calculating the 2-port impedance of the chamber comprises calculating a first parameter of the 2-port impedance by setting the edge electrode as an input/output terminal in a state in which the RF power supply and the impedance matching circuit are connected to the RF electrode.

3. The impedance measurement method as claimed in claim 2, wherein calculating the 2-port impedance of the chamber further comprises calculating a second parameter of the 2-port impedance by setting the edge electrode as an input terminal and setting the RF electrode as an output terminal.

4. The impedance measurement method as claimed in claim 3, wherein calculating the 2-port impedance of the chamber further comprises calculating a third parameter of the 2-port impedance by setting the RF electrode as an input/output terminal in a state in which the edge impedance control circuit is connected to the edge electrode.

5. The impedance measurement method as claimed in claim 1, wherein the 2-port impedance of the chamber is measured in each of a first state in which a wafer-shaped jig is seated on the support unit and a second state in which the jig is not seated on the support unit.

6. The impedance measurement method as claimed in claim 1, further comprising outputting distribution of impedance of the chamber for various frequencies.

7. The impedance measurement method as claimed in claim 6, further comprising outputting an alarm when the distribution of the impedance of the chamber is outside a predetermined reference distribution range.

8. A control device configured to manage a substrate processing apparatus configured to process a substrate using plasma, wherein the substrate processing apparatus comprises:
a chamber forming a processing region for the substrate; and
a support unit disposed at a lower portion in the chamber to support the substrate from below, the support unit including a radio frequency (RF) electrode receiving RF power for generating the plasma and an edge electrode provided on edge of the support unit,
wherein the RF electrode is connected to a RF power supply via an impedance matching circuit, so that the RF power is supplied to the RF electrode,
wherein the edge electrode is connected to an edge impedance control circuit comprising variable impedance elements, so that impedance of a peripheral portion of the support unit is adjusted, and
wherein the control device comprises:
a processor configured to calculate 2-port impedance of the chamber by setting the RF electrode and the edge electrode as 2-port input terminals and 2-port output terminals for various frequencies; and
a memory configured to store data on the 2-port impedance of the chamber.

9. The control device as claimed in claim 8, wherein the processor calculates a first parameter of the 2-port impedance by setting the edge electrode as an input/output terminal in a state in which the RF power supply and the impedance matching circuit are connected to the RF electrode.

10. The control device as claimed in claim 9, wherein the processor calculates a second parameter of the 2-port impedance by setting the edge electrode as an input terminal and setting the RF electrode as an output terminal.

11. The control device as claimed in claim 10, wherein the processor calculates a third parameter of the 2-port impedance by setting the RF electrode as an input/output terminal in a state in which the edge impedance control circuit is connected to the edge electrode.

12. The control device as claimed in claim 8, wherein the 2-port impedance of the chamber is measured in each of a first state in which a wafer-shaped jig is seated on the support unit and a second state in which the jig is not seated on the support unit.

13. The control device as claimed in claim 8, wherein the processor outputs distribution of impedance of the chamber for various frequencies.

14. The control device as claimed in claim 13, wherein the processor outputs an alarm when the distribution of the impedance of the chamber is outside a predetermined reference distribution range.

15. A control device configured to manage a substrate processing apparatus configured to process a substrate using plasma, wherein the substrate processing apparatus comprises:
a chamber configured to define a processing region for the substrate;
a support unit disposed at a lower portion in the chamber to support the substrate from below;
a gas supply unit configured to supply a process gas to an interior of the chamber;
a shower head unit disposed at an upper portion in the chamber to disperse the process gas in the processing region;
a baffle unit disposed between an inner side wall of the chamber and the support unit to discharge a gas remaining in the processing region; and
an radio frequency (RF) power supply configured to supply RF power for generation of the plasma to the support unit,
wherein the support unit comprises:
a dielectric plate configured to allow the substrate to be seated thereon;
a metal plate disposed below the dielectric plate;
an RF plate which is an RF electrode disposed below the metal plate; and
an edge ring assembly disposed on a peripheral portion of the metal plate so as to surround an periphery of the dielectric plate, the edge ring assembly being provided therein with an edge electrode,
wherein the RF plate is connected to the RF power supply via an impedance matching circuit, so that the RF power is supplied to the RF plate,
wherein the edge electrode is connected to an edge impedance control circuit comprising variable impedance elements, so that impedance of a peripheral portion of the support unit is adjusted, and
wherein the control device comprises:
a processor configured to calculate 2-port impedance of the chamber by setting the RF electrode and the edge electrode as 2-port input terminals and 2-port output terminals for various frequencies; and
a memory configured to store data on the 2-port impedance of the chamber.

16. The control device as claimed in claim 15, wherein the processor calculates a first parameter of the 2-port impedance by setting the edge electrode as an input/output terminal in a state in which the RF power supply and the impedance matching circuit are connected to the RF electrode.

17. The control device as claimed in claim 16, wherein the processor calculates a second parameter of the 2-port impedance by setting the edge electrode as an input terminal and setting the RF electrode as an output terminal.

18. The control device as claimed in claim 17, wherein the processor calculates a third parameter of the 2-port impedance by setting the RF electrode as an input/output terminal in a state in which the edge impedance control circuit is connected to the edge electrode.

19. The control device claimed in claim 15, wherein the 2-port impedance of the chamber is measured in each of a first state in which a wafer-shaped jig is seated on the support unit and a second state in which the jig is not seated on the support unit.

20. The control device as claimed in claim 15, wherein the processor outputs distribution of impedance of the chamber for various frequencies, and outputs an alarm when the distribution of the impedance of the chamber is outside a predetermined reference distribution range.
